(19) United States
(12) Patent Application Publication
(10) Pub. No.: US 2007/0257303 A1
(43) Pub. Date: Nov. 8, 2007

(54) Transistor and method for forming the same

(75) Inventors: Jin Hua Liu, Yongin-si (KR); Jong-Hyon Ahn, Suwon-si (KR)

Correspondence Address: HARNESS, DICKEY & PIERCE, P.L.C., P.O. BOX 8910, RESTON, VA, 20195, US

(73) Assignee: SAMSUNG ELECTRONICS., LTD.

(21) Appl. No.: 11/797,429

(22) Filed: May 3, 2007

(30) Foreign Application Priority Data
May 4, 2006 (KR) 10-2006-0040584

(51) Int. Cl. H01L 21/8238; H01L 29/788; H01L 21/3205; H01L 21/4763

(52) U.S. Cl. 257/315; 438/199; 438/585

(57) ABSTRACT

A deep source/drain region and a source/drain extension region may be formed in a semiconductor substrate adjacent to a gate electrode. A first silicide layer may be formed on the source/drain extension region. A gate spacer may be formed on a sidewall of the gate electrode to cover the first silicide layer. A second silicide layer may be formed on the deep source/drain region outside the gate spacer.

### PRIORITY STATEMENT

This U.S. non-provisional patent application claims the benefit of priority to Korean Patent Application No. 10-2006-40584, filed on May 4, 2006, in the Korean Intellectual Property Office, the entire contents of which are incorporated herein in their entirety by reference.

### BACKGROUND

1. Field

Example embodiments relate to a semiconductor device, and for example, to a MOS transistor and/or method for forming the same.

2. Description of Related Art

In manufacturing a transistor, a salicide (for example, a self-aligned silicide) process is widely used to lower resistance of gate and source/drain regions. A shallow junction is formed in order to improve electrical characteristics of a transistor. For example, a parasitic resistance in a source/drain region, for example, sheet resistance or contact resistance, needs to be lowered to reduce a short channel effect caused by a decrease in a gate length. Accordingly, a silicide layer is formed on a surface of the gate and source/drain regions to reduce the resistivity of the gate, and the sheet resistance and the contact resistance of the source/drain region.

FIG. 1 is a cross-sectional view of a conventional MOS transistor. As illustrated in FIG. 1, a gate insulating layer 6 and a gate electrode 8 are sequentially formed in an active region on a semiconductor substrate 2, and a gate silicide layer 16a is formed on the gate electrode 8. A gate spacer 12 is formed on each sidewall of the gate electrode 8. A deep source/drain region 14 is formed in the semiconductor substrate 2 outside the gate spacer 12, and a source/drain extension region 10 is formed in the semiconductor substrate 2 under the gate spacer 12. A silicide layer 16b is formed on a surface of the deep source/drain region 14. An isolation region 4 is formed in the semiconductor substrate at the ends of the deep source/drain region 14.

In the conventional MOS transistor including the source/drain extension region 10, a lower-concentration impurity region decreases an electric field between drain and channel regions, thereby desirably reducing a so-called hot carrier effect in which carriers emitted from a source are rapidly accelerated at a higher voltage.

As the design rule decreases, the gate electrode decreases in length, and the source/drain extension region becomes shallower. Accordingly, the effect of the source/drain extension region on the resistance of the source/drain region is expected to increase. Because the conventional MOS transistor including the source/drain extension region does not include a silicide layer in the source/drain extension region 10 where the gate spacer 12 is formed, series resistance is increased by the source/drain extension region and the deep source/drain region, which causes higher resistance in the entire source/drain region.

### SUMMARY

Example embodiments may provide MOS transistors capable of reducing source/drain resistance, and/or methods for forming the same.

According to an example embodiment, a method for forming a MOS transistor may include forming a gate insulating layer and/or a gate electrode on a semiconductor substrate. A deep source/drain region and/or a source/drain extension region may be formed in a semiconductor substrate outside the gate electrode. A first silicide layer may be formed on the deep source/drain region and/or the source/drain extension region. A gate spacer may be formed on a sidewall of the gate electrode. The gate spacer may cover the source/drain extension region. A second silicide layer may be formed on the deep source/drain region which is not covered by the gate spacer.

According to an example embodiment, the source/drain extension region may be formed after the deep source/drain extension region.

According to an example embodiment, a MOS transistor may include a gate electrode formed on a substrate. A deep source/drain region may be in the semiconductor substrate. The deep source/drain region may be spaced apart from the gate electrode. A source/drain extension region may be in the semiconductor substrate between the deep source/drain region and the gate electrode. A first silicide layer may be on the source/drain extension region. A second silicide layer may be on the deep source/drain region.

According to an example embodiment, the second silicide layer may cover the first silicide layer may cover the entire source/drain extension region.

According to an example embodiment, the MOS transistor may include a gate spacer formed on a sidewall of the gate electrode and completely covering the first silicide layer.

According to another example embodiment, a method for forming a MOS transistor may include forming a gate insulating layer and a gate electrode on a semiconductor substrate. A first spacer may be formed on a sidewall of the gate electrode. Impurity ions may be implanted, using the first spacer and the gate electrode as an ion implantation mask, to form a deep source/drain region in the semiconductor substrate outside the spacer. The first spacer may be removed. Impurity ions may be implanted, by using the gate electrode as an ion implantation mask, to form a source/drain extension region in the semiconductor substrate between the gate electrode and the deep source/drain region. A first silicide layer may be formed on the source/drain extension region and the deep source/drain region. A gate spacer may be formed on a sidewall of the gate electrode. The gate spacer may cover the source/drain extension region. A second silicide layer may be formed on the deep source/drain region which is not covered by the gate spacer.

### BRIEF DESCRIPTION OF THE FIGURES

The above and/or other aspects and advantages will become more apparent and more readily appreciated from the following detailed description of example embodiments taken in conjunction with the accompanying drawings of which:

FIG. 1 is a cross-sectional view of a conventional metal oxide semiconductor (MOS) field effect transistor including a source/drain extension region;

FIG. 2 is a cross-sectional view of a MOS field effect transistor including a source-drain extension region according to an example embodiment;

FIGS. 3A through 3H are cross-sectional views illustrating a method for manufacturing the MOS field effect transistor illustrated in FIG. 2 according to an example embodiment; and

FIGS. 4A through 4D are cross-sectional views illustrating a method for manufacturing a MOS field effect transistor according to another example embodiment.

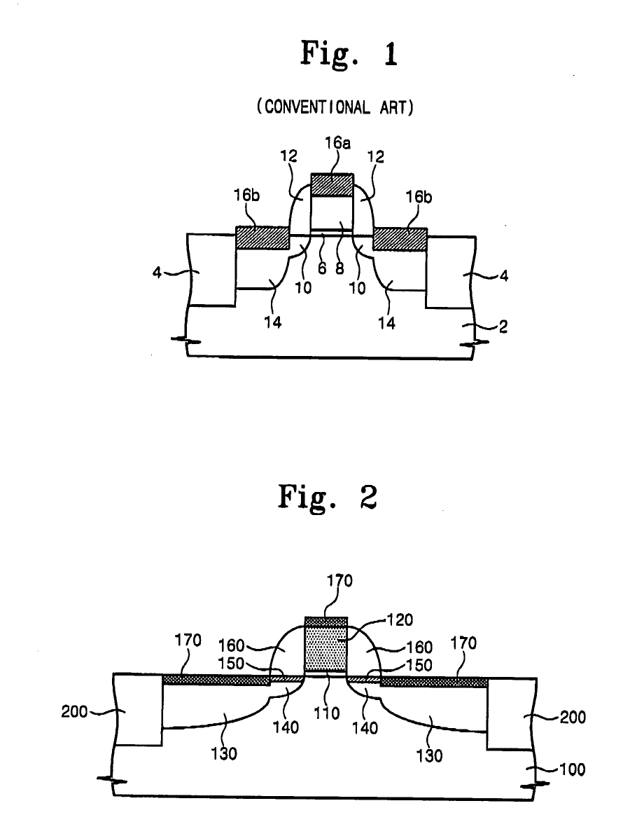

### DETAILED DESCRIPTION OF EXAMPLE EMBODIMENTS

Example embodiments will now be described more fully hereinafter with reference to the accompanying drawings. Embodiments may, however, be in many different forms and should not be construed as being limited to the example embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when a component is referred to as being “on,” “connected to” or “coupled to” another component, it can be directly on, connected to or coupled to the other component or intervening components may be present. In contrast, when a component is referred to as being “directly on,” “directly connected to” or “directly coupled to” another component, there are no intervening components present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one component or feature's relationship to another component(s) or feature(s) as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made to example embodiments, which are illustrated in the accompanying drawings, wherein like reference numerals refer to the like components throughout.

FIG. 2 is a cross-sectional view of a metal oxide semiconductor (MOS) transistor including a source/drain extension region according to an example embodiment.

Referring to FIG. 2, a gate insulating layer 110 and/or a gate electrode 120 may be formed on a semiconductor substrate 100. A source/drain extension region 140 doped with lower-concentration impurities and/or a deep source/drain region 130 doped with higher-concentration impurities may be formed in the semiconductor substrate 100 adjacent to the gate electrode 120. An isolation region 200 may be formed in the semiconductor substrate at ends of the deep source/drain region 130. A first silicide layer 150 and/or a second silicide layer 170 may be formed on the source/drain extension region 140 and/or on the deep source/drain region 130, respectively. The second silicide layer 170 may be formed on the gate electrode 120. A gate spacer 160 may be formed on a sidewall of the gate electrode 120 to cover the source/drain extension region 140. The first silicide layer 150 may be formed on the source/drain extension region 140, and the second silicide layer 170 may be formed on the deep source/drain region 130, thereby reducing series resistance caused by the source/drain extension region 140 and the deep source/drain region 130. Accordingly, the sheet resistance of the source/drain region may be reduced.

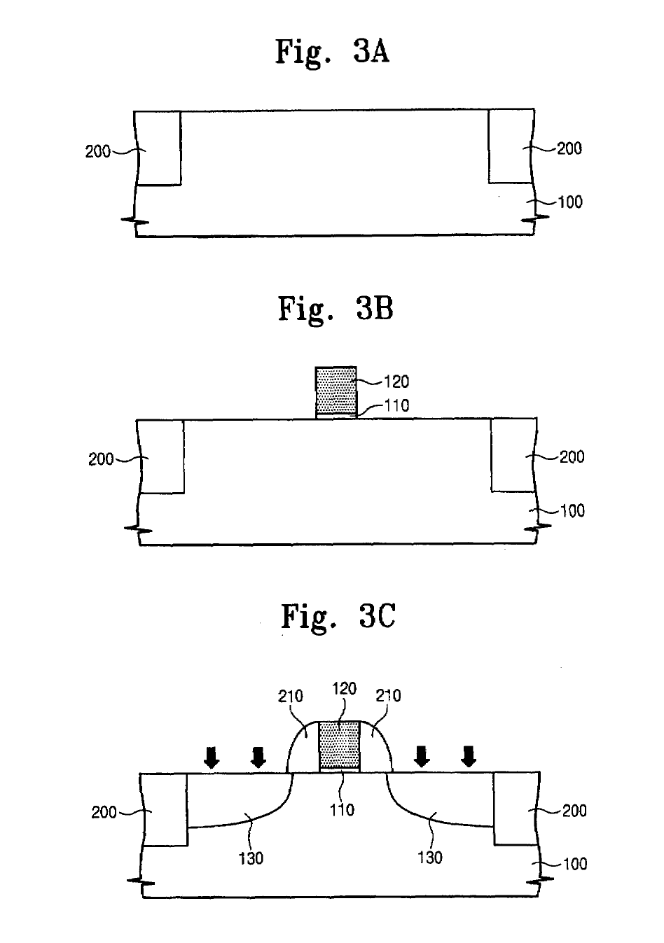

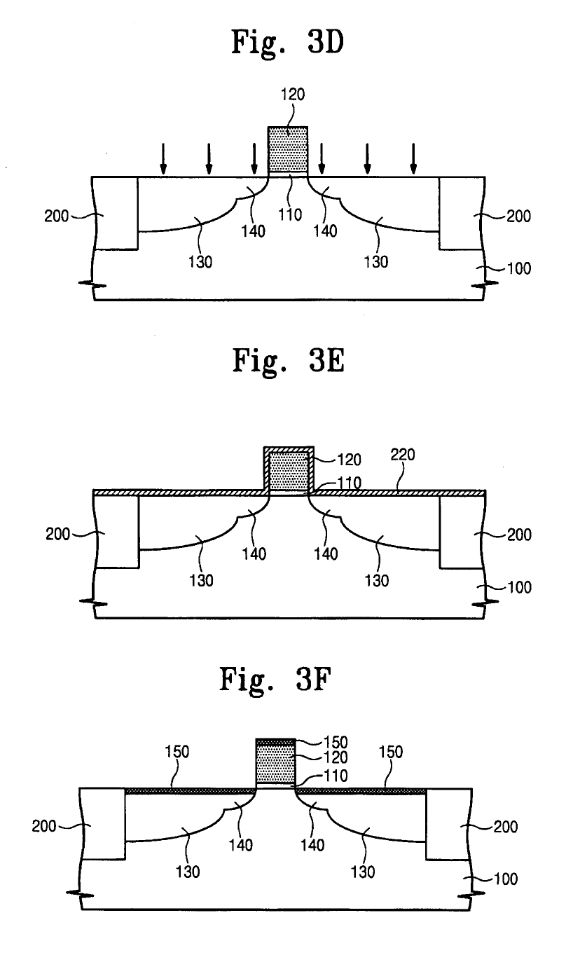

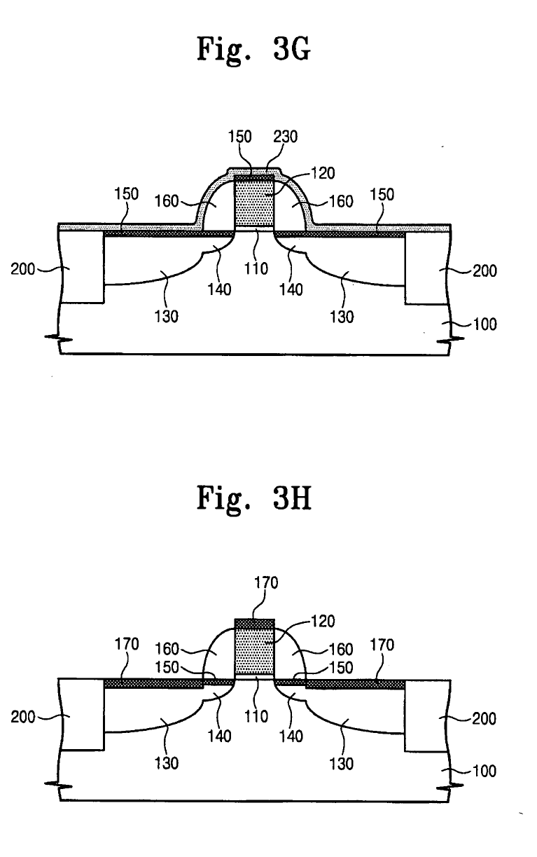

FIGS. 3A through 3H are cross-sectional views illustrating a method for manufacturing the MOS transistor of FIG. 2 according to an example embodiment. Referring to FIG. 3A, the isolation region 200 may be formed in the semiconductor substrate 100. For example, the semiconductor substrate 100 may be a silicon substrate or a silicon on insulator (SOI) substrate, or may be a strained silicon substrate, for example a silicon/germanium substrate. The isolation region 200 may be formed by etching the semiconductor substrate 100 to form a trench, and filling the trench with an insulating material. For example, a shallow trench isolation (STI) may be formed.

Referring to FIG. 3B, the gate insulating layer 110 and the gate electrode 120 may be sequentially formed on an active region of the semiconductor substrate 100. The active region may be defined by the isolation region 200. For example, an insulating layer, for example, an oxide layer, may be formed on the semiconductor substrate 100, and a conductive layer, for example, a polysilicon layer, may be formed on the oxide layer. The insulating layer and the conductive layer may be patterned to form the gate insulating layer 110 and the gate electrode 120. The gate electrode 120 may be formed of polysilicon doped with impurities, or may be formed of a conductive material, for example one of silicon/germanium (SiGe), cobalt (Co), and tungsten (W), or a mixture thereof. A sidewall oxide layer (not shown) may be formed through an oxidation process on a sidewall of the gate electrode 120.

Referring to FIG. 3C, a first spacer 210 may be formed on the sidewall of the gate electrode 120. The first spacer 210 may be used in another process as an ion implantation mask during implantation of higher-concentration impurity ions for forming a deep source/drain region 130. The first spacer 210 may be formed by an insulating-layer deposition process and/or an etch-back process, and may be formed of, for example, a silicon oxide layer, a silicon nitride layer, or the like.

Higher-concentration impurity ions may be implanted using the gate electrode 120 and/or the first spacer 210 as an ion implantation mask, to form a deep source/drain region 130 in the semiconductor substrate 100 outside the first spacer 210.

Referring to FIG. 3D, at least a portion of the first spacer 210 may be removed to expose a substrate region between the gate electrode 120 and the deep source/drain 130 (e.g., a surface of the semiconductor substrate 100 where the source/drain extension region 140 may be formed). The first spacer 210 may be removed by, for example, wet etching. Lower-concentration impurity ions may be implanted into the semiconductor substrate 100 to form a source/drain extension region 140. For example, the gate electrode 120 may be used as an ion implantation mask. The implanted impurity ions may be any desired conductivity type impurities, and/or the implantation concentration for the source/drain extension region 140 may be lower than that of the higher-concentration impurity ions implanted in the deep source-drain region 130.

FIGS. 3E and 3F are cross-sectional views of a process of forming a first silicide layer 150. Referring to FIG. 3E, a first metal layer 220 may be formed on the semiconductor substrate 100 including the gate electrode 120, the deep source/drain region 130, and the source/drain extension region 140. The first metal layer 220 may be formed of at least one metal selected from the group including Co (cobalt), Ni (nickel), Ta (tantalum), Ti (titanium), W (tungsten), Pt (platinum), Hf (hafnium), Pd (palladium), and V (vanadium). The first metal layer 220 may be formed of one of the above-mentioned metal materials, a mixture of at least two of those metal materials, or an alloy thereof. The first metal layer 220 may further include at least one additive selected from the group including Si (silicon), C (carbon), Sc (scandium), Al (aluminum), and Mo (molybdenum), in the metal material. For example, the first metal layer 220 may be formed by depositing a metal material, for example using a sputtering method. Before forming the first metal layer 220, a native oxide layer (not shown) of a semiconductor substrate surface and a gate electrode surface may be removed. After the first metal layer 220 is formed, a capping layer (not shown) may be further formed in order to reduce oxidation of the first metal layer 220 during a heat treatment process. For example, if the first metal layer 220 is formed of Ni (nickel), a layer, for example a TiN (titanium nitride) layer, may be formed on the first metal layer 220 in order to reduce oxidation. The capping layer may be removed through another process.

Referring to FIG. 3F, the semiconductor substrate 100 including the first metal layer 220 may be heat-treated to form the first silicide layer 150. For example, a salicide process may be performed on the deep source/drain region 130, the source/drain extension region 140, and an upper surface of the gate electrode 120, thereby forming the first silicide layer 150. Alternatively, the first silicide layer 150 may not be formed on the upper surface of the gate electrode 120 depending on a material constituting the gate electrode 120.

The heat treatment of the first metal layer 220 for forming the first silicide layer 150 may be performed through one heat treatment process, or two or more heat treatment processes. For example, if the first metal layer 220 is formed using Co as a main component, a first heat treatment may be performed in a rapid thermal annealer (RTA) at a heat-treatment temperature of about 400° C. to about 600° C., so that the Co reacts to a Si component, forming CoSi (cobalt monosilicide), for example an intermediate layer. The first metal layer which does not react to the silicon component during the first heat treatment may be removed, and a second heat treatment may be performed at a heat treatment temperature of about 700° C. or higher so that phase-transition may occur from CoSi to CoSi₂ (cobalt disilicide) having lower resistance.

According to another example embodiment, the first metal layer may be formed of Ni. In this case, the first heat treatment may be performed at a temperature ranging from about 300° C. to about 400° C. so that the Ni of the Ni layer reacts to a silicon component, thereby forming a Ni₂Si (dinickel silicide). A nickel component that does not react to the silicon component may be removed, and/or a second heat treatment may be performed at a temperature ranging from about 300° C. to about 600° C. so that phase-transition to NiSi (nickel silicide) having lower resistivity may be made.

FIGS. 3G and 3H are cross-sectional views illustrating a process of forming the second silicide layer 170. Referring to FIG. 3G, the gate spacer 160 may be formed on a sidewall of the gate electrode 120. For example, the gate spacer 160 may be formed on a portion of the first spacer 210 remaining on the sidewall of the gate electrode 120 that is not removed during the removing process of the first spacer 210. However, the first spacer 210 may be entirely removed during the removing process of the first spacer 210 and the gate spacer 160 may be formed directly on a sidewall of the gate electrode 120. The gate spacer 160 may be formed of a single layer of, for example, a silicon oxide layer or a silicon nitride layer, or double layers thereof. The gate spacer 160 may be formed to cover the source/drain extension region 140.

A second metal layer 230 may be formed on the semiconductor substrate 100 including the first silicide layer 150 and the gate spacer 160. The second metal layer 230 may be formed of at least one metal material selected from the group including Co (cobalt), Ni (nickel), Ta (tantalum), Ti (titanium), W (tungsten), Pt (platinum), Hf (hafnium), Pd (palladium), and V (vanadium). The second metal layer 230 may be formed of one of the above-mentioned metal materials, a mixture of at least two of those metal materials, or an alloy thereof. The first metal layer 230 may further include at least one additive selected from the group including Si (silicon), C (carbon), Sc (scandium), Al (aluminum), and Mo (molybdenum) in the metal material. The second metal layer 230 may be formed of the same material as that of the first metal layer 220, or a different material. A capping layer (not shown) may be further formed on the second metal layer 230 to reduce oxidation.

Referring to FIG. 3H, a heat treatment may be performed on the second metal layer 230 to form a second silicide layer 170 on the first silicide layer 150 which is not covered by the gate spacer 160. In the case where the gate spacer 160 covers the source/drain extension region 140, a salicide process is performed on the deep source/drain region 130 and/or an upper surface of the gate electrode 120 to form the second silicide layer 170 on the first silicide layer 150. Alternatively, no silicide layer 170 may be formed on the upper surface of the gate electrode 120 depending on a material constituting the gate electrode 120.

The heat treatment on the second metal layer 230 for formation of the second silicide layer 170 may be performed through a one step heat treatment process, or two or more step heat treatment processes. Because the salicide process described above is substantially similar to the salicide process for formation of the second silicide layer 170, a detailed description thereof will be omitted.

The second silicide layer 170 on the seep source/drain region 130 may be formed thicker than the first silicide layer 150 on the source/drain extension region 140. Because the first silicide layer 150 may be formed on the lower-concentration source/drain extension region 140, the first silicide layer 150 may be formed to be thin enough to reduce junction breakdown between the lower-concentration impurity region and the semiconductor substrate 100. As for the silicide layers formed for a resistance decrease, the second silicide layer 170 formed on the higher-concentration deep source/drain region 130 may be thicker than the first silicide layer 150 formed on the lower-concentration source/drain extension region 140.

In another process, a local conductive line may be formed, which may be connected to the deep source/drain region 130.

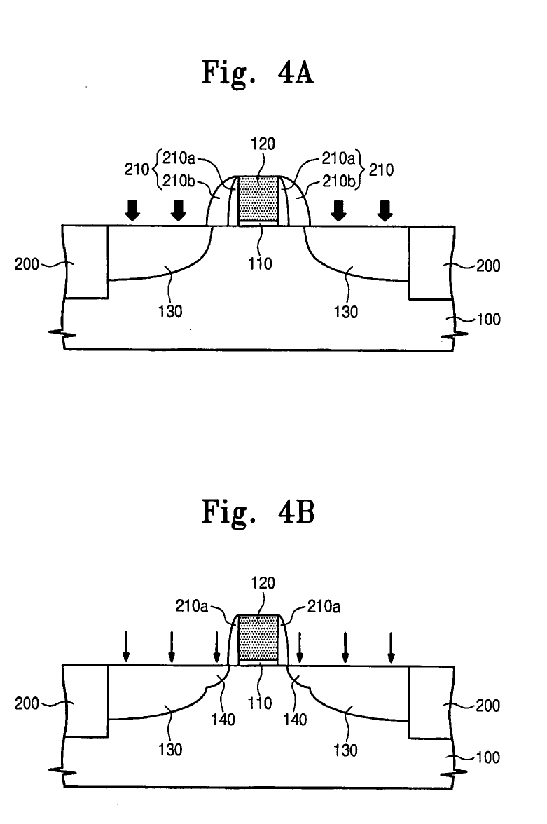

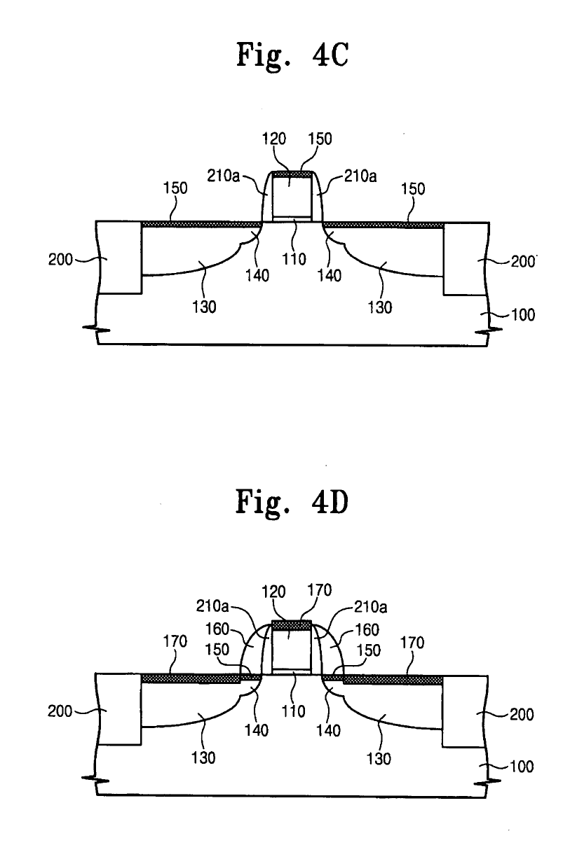

Although the first spacer 210 in FIG. 3C may be formed of a single layer in an example embodiment described above, the first spacer 210 may be formed of multiple layers. For example, the spacer 210 may be formed of an inner insulating layer formed adjacent to the sidewall of the gate electrode 120, and an outer insulating layer formed adjacent to the inner insulating layer. For example, a silicon oxide layer may be used as the inner insulating layer, and/or a silicon nitride layer may be used as the outer insulating layer. An example embodiment including the first spacer 210 formed of multiple layers will be described with reference to FIGS. 4A through 4D. The same manufacturing processes as those illustrated with reference to FIGS. 3A through 3H will be described briefly in order to avoid duplication of the description.

Referring to FIG. 4A, the processes described above with reference to FIGS. 3A and 3B may be performed to form an isolation region 200, a gate insulating layer 110, and a gate electrode 120 at a substrate 100. A first spacer 210 including an inner spacer 210a (e.g., an inner insulating layer) and an outer spacer 210b (e.g., an outer insulating layer) may be formed on a sidewall of the gate electrode 120. The inner spacer 210a and the outer spacer 210b may be formed of materials having etching selectivity with respect to each other. For example, the inner spacer 210a may be formed of a silicon nitride layer, and the outer spacer 210b may be formed of a silicon oxide layer. Alternatively, the inner spacer 210a may be formed of a silicon oxide layer, and the outer spacer 210b may be formed of a silicon nitride layer.

Still referring to FIG. 4A, an implantation process of higher-concentration impurity ions may be performed to form a deep source/drain region 130.

Referring to FIG. 4B, the outer spacer 210b may be selectively removed, and an implantation process of lower-concentration impurity ions may be performed to form a source/drain extension region 140 in the semiconductor substrate exposed by the removal of the outer spacer 210b. The outer spacer 210b may be selectively removed by using an etching solution or an etching gas having etching selectivity between the inner insulating layer and the outer insulating layer.

Referring to FIG. 4C, a deposition process of a first metal layer, and/or a heat treatment process on the first metal layer may be performed to form a first silicide layer 150 on the source/drain extension region 140, the deep source/drain region 130, and the gate electrode 120.

Referring to FIG. 4D, a gate spacer 160 is formed on the inner spacer 210a on the gate sidewall 120, and then a deposition process of a second metal layer, and a heat treatment process on the second metal layer are performed to form a second silicide layer 170 on the deep source/drain region 130 and the gate electrode 120.

In example embodiments illustrated with reference to FIGS. 4A through 4D, in the case where the gate electrode may be formed of polysilicon, and the inner spacer 210a may be formed of a silicon oxide layer, an inner oxide layer may be formed through a thermal oxidation process. For example, the thermal oxidation process for the inner oxide layer may additionally serve to cure damage of the gate insulating layer 110 caused during an etching process for forming the gate electrode.

In the above-described example embodiments, after the deep source-drain region 130 and the source/drain extension regions 140 are formed, an annealing process may be performed. The annealing process may be performed before the process of forming the silicide layers. For example, before forming the first silicide layer 150. For example, the annealing process may be performed at a relatively low temperature in comparison with the case where the annealing process is performed on the deep source/drain region and the source/drain extension region after the silicide layer is formed.

According to the above-described example embodiments, because the source/drain extension region 140 may be formed after formation of the deep source/drain region 130, the source/drain extension region 140 may not be exposed to the process of forming the deep source/drain extension region. If the source/drain extension region is formed before the formation of the deep source/drain region, the source/drain extension region may be exposed to a higher-temperature process for forming a spacer for the deep source/drain region, causing breakdown of a shallow junction between the source/drain extension region 140 and the semiconductor substrate 100. Accordingly, a short-circuit problem may result.

According to an example embodiment, a silicide layer may be formed on a source/drain extension region doped with lower-concentration impurity ions, so that sheet resistance may be reduced.

An annealing process may be performed on the deep source/drain region and/or the source/drain extension region before the process of forming the silicide layers, thereby achieving a higher annealing effect.

Because the source/drain extension region 140 may be formed after the deep source/drain region 130 is formed, the breakdown of a shallow junction between the source/drain extension region and the semiconductor substrate, which may occur during a process of forming a spacer at a higher-temperature for the implantation of higher-concentration impurity ions, may be reduced.

Although example embodiments have been shown and described in this specification and figures, it would be appreciated by those skilled in the art that changes may be made to the illustrated and/or described example embodiments without departing from their principles and spirit.

What is claimed is:

1. A method for forming a transistor, the method comprising:
forming a gate insulating layer and a gate electrode on a semiconductor substrate;
forming a deep source/drain region and a source/drain extension region in the semiconductor substrate outside the gate electrode;
forming a first silicide layer on the source/drain extension region;
forming a gate spacer on a sidewall of the gate electrode, the gate spacer covering the source/drain extension region; and
forming a second silicide layer on the deep source/drain region outside the gate spacer.

2. The method of claim 1, wherein forming the first silicide layer includes,
forming a first metal layer on the semiconductor substrate including the deep source/drain region and the source/drain extension region; and
performing a heat treatment on the semiconductor substrate.

3. The method of claim 2, wherein the first metal layer includes at least one metal selected from the group including cobalt (Co), nickel (Ni), tantalum (Ta), titanium (Ti), tungsten (W), platinum (Pt), hafnium (Hf), palladium (Pd), and vanadium (V).

4. The method of claim 3, wherein the first metal layer includes at least one additive selected from the group including silicon (Si), carbon (C), scandium (Sc), aluminum (Al) and molybdenum (Mo), in the at least one metal.

5. The method of claim 2, wherein performing the heat treatment includes,
performing a first heat treatment to form an intermediate layer by reaction between a metal of the first metal layer and silicon; and
performing a second heat treatment to form the first silicide layer.

6. The method of claim 1, wherein forming the deep source/drain region and the source/drain extension region in the semiconductor substrate includes,
forming the source/drain extension region after forming the deep source/drain region.

7. The method of claim 6, wherein forming the source/drain extension region and the deep source/drain region includes,
forming a first spacer on the sidewall of the gate electrode;
implanting higher-concentration impurity ions using the gate electrode and the first spacer as an ion implantation mask to form the deep source/drain region in the semiconductor substrate;
removing at least a portion of the first spacer to expose a surface of the semiconductor substrate between the gate electrode and the deep source/drain region; and
implanting lower-concentration impurity ions using the gate electrode as an ion implantation mask to form the source/drain extension region in the semiconductor substrate.

8. The method of claim 7, wherein forming the first spacer on the sidewall of the gate electrode includes,
forming an inner insulating layer on the sidewall of the gate electrode; and
forming an outer insulating layer on the inner insulating layer,
wherein removing of at least a portion of the first spacer includes removing the outer insulating layer.

9. The method of claim 8, wherein the inner insulating layer is one of a silicon oxide layer and a silicon nitride layer, the outer insulating layer is one of a silicon nitride layer and a silicon oxide layer, and the inner insulating layer is different than the outer insulating layer.

10. The method of claim 1, further comprising:
annealing the deep source/drain region and the source/drain extension region after forming the deep source/drain region and the source/drain extension region in the semiconductor substrate, and before forming the first silicide layer.

11. The method of claim 1, wherein forming the second silicide layer includes,
forming a second metal layer on the semiconductor substrate including the first silicide layer; and
performing a heat treatment on the second metal layer.

12. The method of claim 11, wherein the second metal layer includes at least one metal selected from the group including cobalt (Co), nickel (Ni), tantalum (Ta), titanium (Ti), tungsten (W), platinum (Pt), hafnium (Hf), palladium (Pd), and vanadium (V).

13. The method of claim 1, wherein the second silicide layer is thicker than the first silicide layer.

14. The method of claim 1, wherein the semiconductor substrate is one of a silicon substrate, a gate germanium substrate, a silicon-on-insulator (SOI) substrate, and a strained silicon substrate.

15. A transistor comprising:
a gate electrode on a semiconductor substrate;
a deep source/drain region in the semiconductor substrate, the deep source/drain region being spaced apart from the gate electrode;
a source/drain extension region in the semiconductor substrate between the deep source/drain region and the gate electrode;
a first silicide layer on the source/drain extension region; and
a second silicide layer on the deep source/drain region.

16. The transistor of claim 15, further comprising:
an inner spacer on a sidewall of the gate electrode; and
a gate spacer on a sidewall of the inner spacer and covering the first silicide layer.

17. The transistor of claim 15, further comprising:
a gate spacer on a sidewall of the gate electrode and covering the first silicide layer.

18. The transistor of claim 15, wherein the second silicide layer is thicker than the first silicide layer.

19. The method of claim 1, wherein forming the deep source/drain region and the source/drain extension region in the semiconductor substrate includes,
forming a first spacer on the sidewall of the gate electrode;
implanting impurity ions using the first spacer and the gate electrode as an ion implantation mask to form the deep source/drain region in the semiconductor substrate outside the first spacer;
removing the first spacer; and
after removing the first spacer, implanting impurity ions by using the gate electrode as an ion implantation mask to form the source/drain extension region in the semiconductor substrate between the gate electrode and the deep source/drain region.

20. The method of claim 19, wherein the forming first spacer on the sidewall of the gate electrode includes,
forming an inner insulating layer on the sidewall of the gate electrode; and
forming an outer insulating layer on the inner insulating layer,
wherein removing the first spacer includes removing the outer insulating layer.
